(19) United States
(12) Patent Application Publication
(10) Pub. No.: US 2025/0055313 A1
(43) Pub. Date: Feb. 13, 2025

(54) ELECTRIC OUTAGE CONFIRMATION APPARATUS, POWER SUPPLY DEPLETION CONFIRMATION APPARATUS, ELECTRIC OUTAGE CONFIRMATION METHOD, POWER SUPPLY DEPLETION CONFIRMATION METHOD, AND PROGRAM

(71) Applicant: NIPPON TELEGRAPH AND TELEPHONE CORPORATION, Tokyo (JP)

(72) Inventors: Ryo SATO, Tokyo (JP); Tomonari FUJIMOTO, Tokyo (JP); Motomu NAKAJIMA, Tokyo (JP)

(21) Appl. No.: 18/722,263

(22) PCT Filed: Dec. 21, 2021
(86) PCT No.: PCT/JP2021/047369

§ 371 Date: Jun. 20, 2024

(51) Int. Cl. H02J 13/00; G01R 19/25

(52) U.S. Cl. CPC H02J 13/00002; G01R 19/2513; H02J 13/00006

(57) ABSTRACT

A power outage confirmation device that confirms whether a power outage has occurred in an area including a communication building and a plurality of subscribed users accommodated in the communication building includes: a user confirmation unit that acquires information on the plurality of subscribed users in a case where a communication abnormality is detected from a power monitoring device; a subscription log confirmation unit that confirms a log of an in-home device of each of the subscribed users on the basis of the information; and a power outage determination unit that determines whether a power outage has occurred in the area on the basis of the log.

### TECHNICAL FIELD

The present invention relates to a technique for monitoring a power supply status of a communication station building.

### BACKGROUND ART

A communication station building (which may also be referred to as a communication building) accommodating communication facilities of a communication carrier or the like includes a power supply device, a battery, and the like, as well as various transmission devices and the like. The power supply device supplies commercial power to the transmission devices and the like. In a case where the power supply by commercial power is stopped due to a power outage, power supply by a battery is performed.

As a conventional technique for monitoring a power supply status of a communication station building, there is a technique in which a power monitoring device periodically polls a power supply device via a communication network (referred to as a power monitoring network) to monitor the power supply status of the communication station building (for example, Non Patent Literature 1).

### CITATION LIST

### Non Patent Literature

Non Patent Literature 1: https://www.ntt-f.co.jp/news/heiseil8/h18-1214.html, searched on Nov. 15, 2021

### SUMMARY OF INVENTION

### Technical Problem

A power monitoring network for monitoring a power supply device may fail due to a disaster or the like. In the conventional technique, in a case where the power monitoring network fails, it is not possible to grasp a power supply status of a communication station building.

The present invention has been made in view of the above point, and an object of the present invention is to provide a technique that makes it possible to grasp a power supply status in a communication station building even in a case where a power monitoring network fails.

### Solution to Problem

According to the disclosed technique, there is provided a power outage confirmation device that confirms whether a power outage has occurred in an area including a communication building and a plurality of subscribed users accommodated in the communication building,
the power outage confirmation device including:
a user confirmation unit that acquires information on the plurality of subscribed users in a case where a communication abnormality is detected from a power monitoring device;
a subscription log confirmation unit that confirms a log of an in-home device of each of the subscribed users on the basis of the information; and
a power outage determination unit that determines whether a power outage has occurred in the area on the basis of the log.

### Advantageous Effects of Invention

According to the disclosed technique, it is possible to grasp a power supply status in a communication station building even in a case where a power monitoring network fails.

### BRIEF DESCRIPTION OF DRAWINGS

FIG. 1 is a diagram for describing a problem.

FIG. 2 is a diagram for describing the problem.

FIG. 3 is a diagram for describing a problem.

FIG. 4 is a diagram for describing an outline of an embodiment.

FIG. 5 is an overall configuration diagram of a system.

FIG. 6 is a diagram illustrating a device configuration.

FIG. 7 is a flowchart of commercial power outage confirmation.

FIG. 8 is a flowchart of building power source exhaustion confirmation.

FIG. 9 is a diagram illustrating a hardware configuration example of a device.

### DESCRIPTION OF EMBODIMENTS

Hereinafter, an embodiment of the present invention (present embodiment) will be described with reference to the drawings. The embodiment described below is merely an example, and embodiments to which the present invention is applied are not limited to the following embodiment.

### Problems

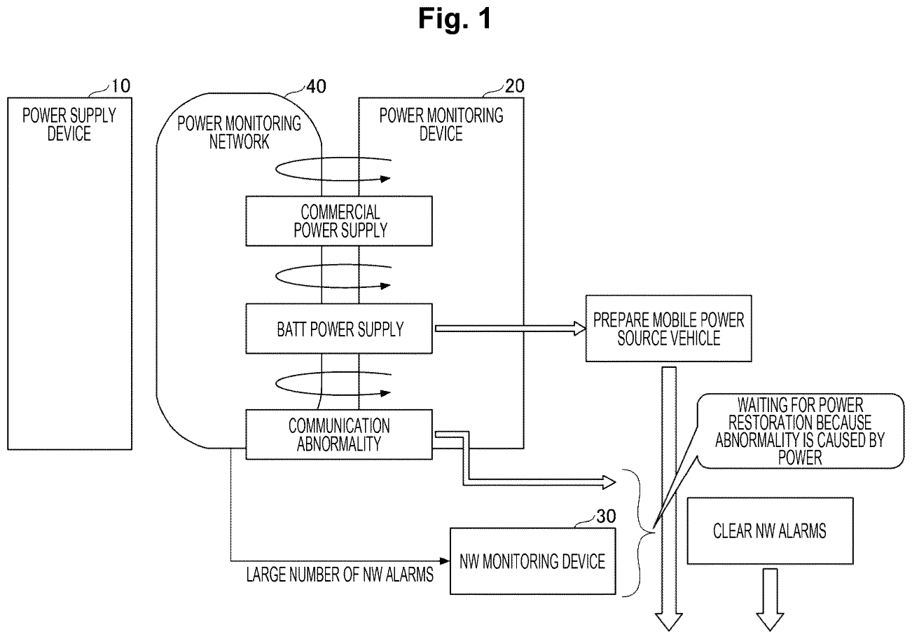

First, problems relating to the technique of the present embodiment will be described in detail with reference to the drawings. Note that the contents of the following description of the problems (and FIGS. 1 to 3) are contents for analyzing a conventional technique and describing the problems, and are not known contents.

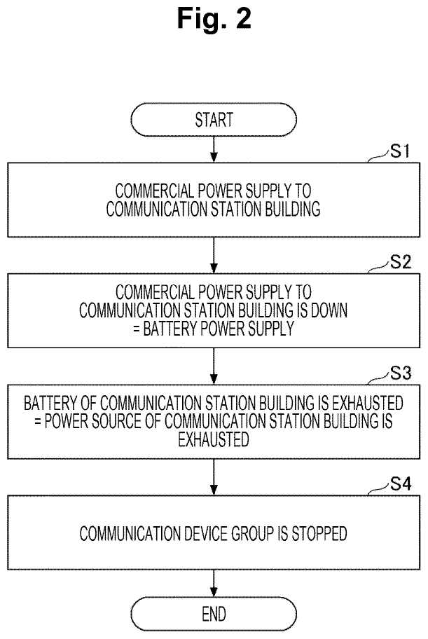

With reference to FIGS. 1 and 2, an example of a configuration and a procedure of monitoring at the time of disaster (power outage) in the conventional technique will be described. As illustrated in FIG. 1, a power supply device 10 is provided in a communication station building, and a power monitoring device 20 monitors the power supply device 10 via a power monitoring network 40. In addition, a NW monitoring device 30 monitors the power monitoring network 40.

Note that it is assumed that the power monitoring device 20 and the NW monitoring device 30 are provided in a place (such as a monitoring center) different from the communication station building where the power supply device 10 is provided.

The monitoring situation illustrated in FIG. 1 will be described along the procedure of the flowchart of FIG. 2. In S1, the power supply device 10 normally performs commercial power supply to the communication station building. The power monitoring device 20 periodically polls the power supply device 10 via the power monitoring network 40, and at this time, grasps that commercial power supply is normally performed.

In S2, due to a power outage of the communication station building, commercial power supply is down, and battery power supply is started. Since the power monitoring device 20 outputs a monitoring result indicating that commercial power supply is down and battery power supply is started, an operator (person) grasps the monitoring result and prepares a mobile power source vehicle in preparation for battery exhaustion.

In S3, the battery of the communication station building is exhausted. That is, a power source of the communication station building is exhausted. Accordingly, in S4, a communication device group is stopped.

When the power source of the communication station building is exhausted, the power supply device 10 is also stopped due to the power source exhaustion, and thus the power monitoring device 20 outputs “communication abnormality” as in a case where the power monitoring network 40 fails. In addition, a large number of NW alarms are output from the power monitoring network 40. However, in this case, it is known that the “communication abnormality” is caused by power exhaustion, and thus it is possible to wait for the power to recover.

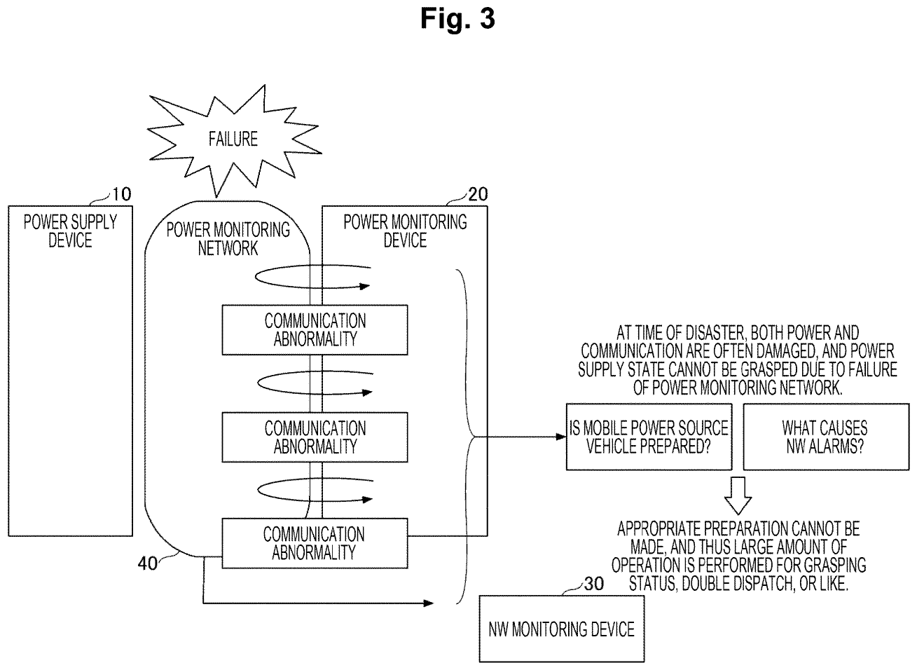

A case where the power monitoring network 40 (communication network) fails at the time of disaster or the like as in the case illustrated in FIG. 1 will be described with reference to FIG. 3. At the time of disaster, both power and communication are often damaged, and thus the case of FIG. 3 is likely to occur.

Although the power monitoring network 40 of the communication station building is generally duplicated, there is a case where both the two systems are disconnected at the time of disaster, and in this case, the state of the power supply device 10 cannot be grasped from the power monitoring device 20.

At this time, as illustrated in FIG. 2, although “communication abnormality” is output from the power monitoring device 20, it is not possible to grasp the power supply status, and thus, there is a possibility that a lot of wasteful operation may be performed because appropriate preparation cannot be made due to lack of information. For example, double dispatch, which includes dispatch of a failure repair group of communication facilities and dispatch of a mobile power source vehicle, may cause the repair group to be idle.

Although it is conceivable to perform power monitoring of communication station buildings across the country by triplicated networks, this is not realistic because the cost is too high.

Therefore, a technique is necessary for determining the power supply state (commercial power supply, battery power supply, power loss, or the like) of the communication station building even when the power monitoring network 40 is disconnected. Hereinafter, the technique will be described.

### Outline of Embodiment

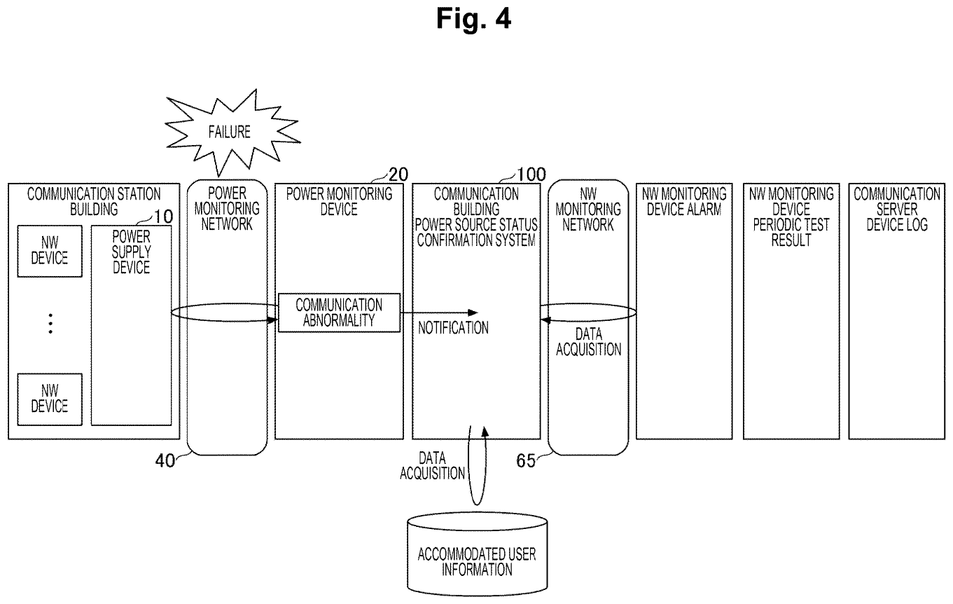

An outline of the present embodiment will be described with reference to FIG. 4. In the present embodiment, even in a case where the power monitoring network 40 fails, a communication building power source status confirmation system 100 illustrated in FIG. 4 can grasp the state of the communication station building, such as “commercial power outage” or “power source exhaustion”, using a communication network.

That is, as illustrated in FIG. 4, in the present embodiment, the state of the communication station building, such as “commercial power outage” or “power source exhaustion” is grasped by use of information such as accommodated user information, a NW monitoring device alarm, a NW monitoring device periodic test result, and a communication server device log, which can be used even in a case where the communication station building including the power supply device 10 is damaged by a disaster.

Specifically, the communication building power source status confirmation system 100 confirms users (meaning the users' homes) whose power supply area is the same as that of the target communication station building from a log and monitoring data of a network device, and determines that a power outage has occurred in the area including the communication station building when communication of a plurality of users is disconnected at the same time. In addition, when there is a power outage, it is determined that commercial power supply cannot be performed even in the communication station building. The above area is an area including the communication station building and the plurality of subscribed users accommodated in the communication station building.

If it is found that the commercial power supply cannot be performed, for example, it is possible to make an arrangement such that a mobile power source vehicle can arrive before the battery exhaustion time of the building.

In addition, a communication test is performed from transmission devices in other communication buildings connected to a transmission device in the communication station building where a communication abnormality has been observed as a result of power monitoring so that connection states are grasped, and in a case where all the connection states are no good, it is determined that the power source of the communication station building where the communication abnormality has been observed as a result of the power monitoring is exhausted.

With the technique according to the present embodiment, communication confirmation is performed on all the relay lines (transmission paths) connected to the target communication station building, and thus, it is possible to accurately determine whether a plurality of relay lines is disconnected or the building power source is exhausted. Therefore, it is not necessary to dispatch both the mobile power source vehicle and a transmission path repair group, which enables reduction in operation. Hereinafter, the present embodiment will be described in more detail.

### System Configuration Example

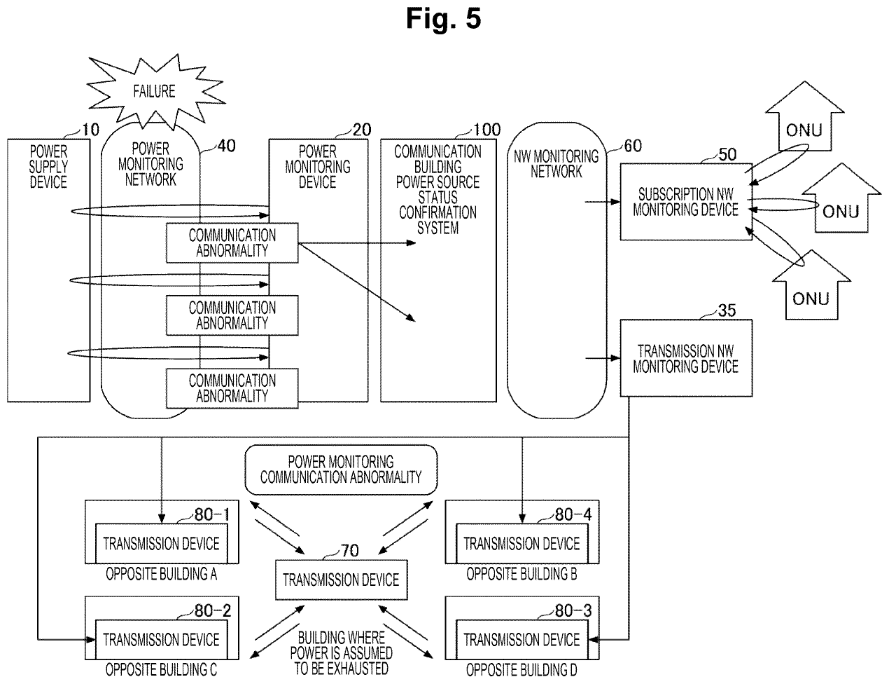

FIG. 5 illustrates an overall configuration example of the system according to the present embodiment. FIG. 5 illustrates, together with the configuration, that “communication abnormality” is output when the power monitoring network 40 fails.

The power supply device 10 is provided in the target communication station building, and normally supplies power to a transmission device 70 and the like in the communication station building. The power monitoring device 20 monitors the power supply device 10 by polling via the power monitoring network 40 as described above.

Even in a case where the power monitoring network 40 fails, the communication building power source status confirmation system 100 grasps the state of the communication station building, such as “commercial power outage” or “power source exhaustion”, using a communication network.

In addition, as illustrated in FIG. 5, there is a plurality of subscribed users (having in-home devices such as ONUs in their homes) in an area of the target communication station building (an area where commercial power supply is stopped when commercial power supply to the communication station building is stopped), and the respective in-home devices of the subscribed users are monitored by a subscription NW monitoring device 50.

In addition, a transmission NW monitoring device 35 can monitor transmission devices 80-1 to 80-4 provided in communication station buildings.

In the configuration of FIG. 5, it is assumed that the target communication station building including the power supply device 10 and the transmission device 70 is different in location from “the power monitoring device 20, the communication building power source status confirmation system 100, the subscription NW monitoring device 50, and the transmission NW monitoring device 35”, and even if the power source of the target communication station building is exhausted, power is supplied to each of the power monitoring device 20, the communication building power source status confirmation system 100, the subscription NW monitoring device 50, the transmission NW monitoring device 35, and the like, and these devices are operating.

### (Configuration of Communication Building Power Source Status Confirmation System 100)

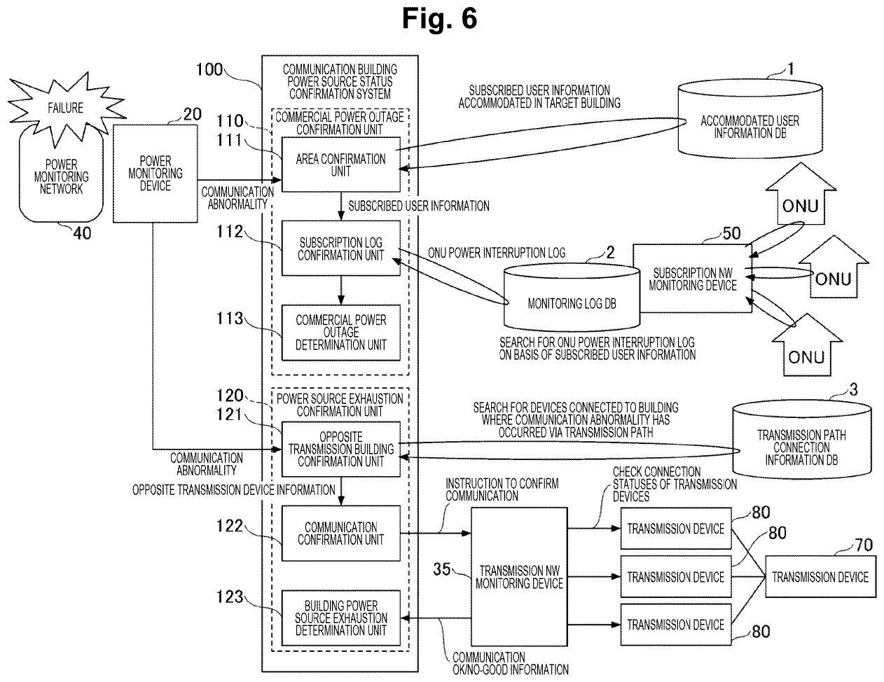

FIG. 6 is a diagram illustrating an internal configuration of the communication building power source status confirmation system 100. As illustrated in FIG. 6, the communication building power source status confirmation system 100 includes a commercial power outage confirmation unit 110 and a power source exhaustion confirmation unit 120.

Note that the communication building power source status confirmation system 100 may include one device (computer) or may include a plurality of devices. For example, each of the commercial power outage confirmation unit 110 and the power source exhaustion confirmation unit 120 may be one device (computer). The commercial power outage confirmation unit 110 and the power source exhaustion confirmation unit 120 may be referred to as a power outage confirmation device and a power source exhaustion confirmation device, respectively.

In addition, the communication building power source status confirmation system 100 may be referred to as a power outage confirmation device or a power source exhaustion confirmation device.

### <Commercial Power Outage Confirmation Unit 110>

The commercial power outage confirmation unit 110 is a functional unit that determines whether a commercial power outage has occurred by referring to a subscription NW alarm or the like, and includes an area confirmation unit 111, a subscription log confirmation unit 112, and a commercial power outage determination unit 113. The commercial power outage determination unit 113 may be referred to as a power outage determination unit.

The area confirmation unit 111 acquires, from an accommodated user information DB 1, subscribed user information accommodated in the communication station building where the communication abnormality has occurred. Note that the accommodated user information DB 1 is provided, for example, in the subscription NW monitoring device 50.

On the basis of the subscribed user information, the subscription log confirmation unit 112 confirms whether an ONU (in-home device) at a user's home indicated by the subscribed user information is outputting a power-off log on the basis of information in a monitoring log DB 2. The monitoring log DB 2 is a DB provided in the subscription NW monitoring device 50, and stores a log of a monitoring result by the subscription NW monitoring device 50.

The commercial power outage determination unit 113 determines whether a commercial power outage has occurred in the communication station building and its surroundings on the basis of the confirmation result by the subscription log confirmation unit 112.

### <Power Source Exhaustion Confirmation Unit 120>

The power source exhaustion confirmation unit 120 is a functional unit that determines whether the power source of the communication station building including the battery is exhausted, and includes an opposite transmission building confirmation unit 121, a communication confirmation unit 122, and a building power source exhaustion determination unit 123.

The opposite transmission building confirmation unit 121 collects, from transmission path connection information stored in a transmission path connection information DB 3, information on transmission devices in opposite buildings connected via transmission paths to the transmission device in the communication station building where the communication abnormality has occurred. The transmission path connection information DB 3 is provided, for example, in the transmission NW monitoring device 35. Note that the opposite transmission building confirmation unit 121 may be referred to as an opposite transmission device confirmation unit.

The communication confirmation unit 122 uses the transmission NW monitoring device 35 to confirm communication (connectivity) from each opposite transmission device to the transmission device in the communication station building where the communication abnormality has occurred (target communication station building).

The building power source exhaustion determination unit 123 determines whether the power source of the target communication station building is exhausted on the basis of the communication OK/no-good information.

### (Operation Example of Commercial Power Outage Confirmation Unit 110)

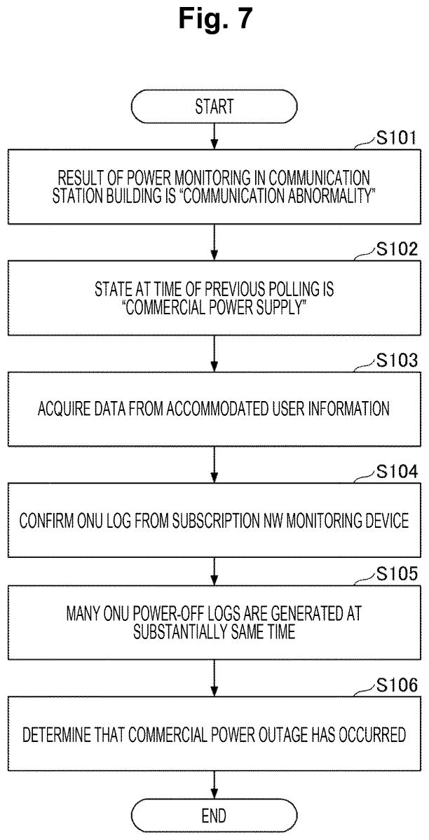

An operation example of the commercial power outage confirmation unit 110 illustrated in FIG. 6 will be described along the procedure of the flowchart of FIG. 7.

In S101, the area confirmation unit 111 receives, from the power monitoring device 20, “communication abnormality” as a polling result in a certain communication station building (referred to as a target communication station building).

When it is confirmed in S102 that the state at the time of the previous polling by the power monitoring device 20 is “commercial power supply”, the area confirmation unit 111 acquires, in S103, subscribed user information accommodated in the target communication station building where the communication abnormality has occurred from the accommodated user information DB 1.

In S104, on the basis of the subscribed user information, the subscription log confirmation unit 112 confirms whether an ONU at the user's home is outputting a power-off log on the basis of information in the monitoring log DB 2.

When it is confirmed in S105 that many ONU power-off logs are generated at substantially the same time on the basis of the confirmation result by the subscription log confirmation unit 112, the commercial power outage determination unit 113 determines in S106 that a power outage of commercial power has occurred in a target area (area including the target communication station building and the accommodated subscribed users' homes), and outputs the determination result.

Note that, in the determination, for example, it is determined that a power outage of commercial power has occurred in a case where ONU power-off logs are generated within a certain time range in ONUs of users whose number is equal to or greater than a threshold (%) in the number of users to be subjected to log confirmation, which is included in the subscribed user information. In this example, the ONU power-off logs are used for determination, but register information or the like of a SIP server may be used for determination.

### (Operation Example of Power Source Exhaustion Confirmation Unit 120)

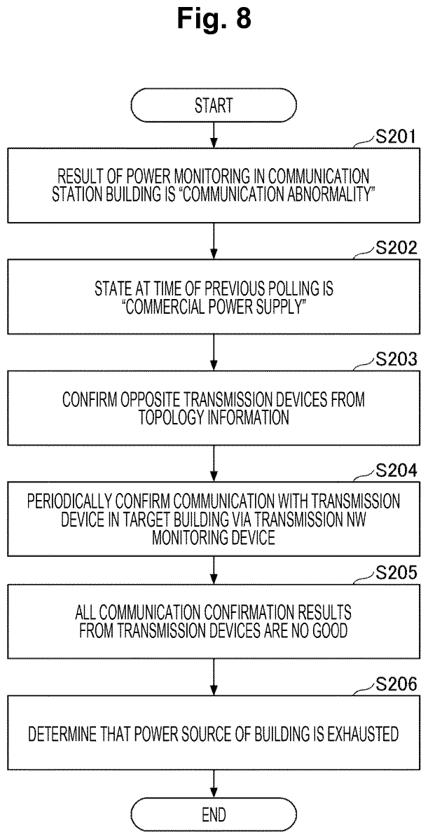

Next, an operation example of the power source exhaustion confirmation unit 120 illustrated in FIG. 6 will be described along the procedure of the flowchart of FIG. 8.

In S201, the opposite transmission building confirmation unit 121 receives, from the power monitoring device 20, “communication abnormality” as a polling result for a certain communication station building (referred to as a target communication station building).

When it is confirmed in S202 that the state at the time of the previous polling by the power monitoring device 20 is “commercial power supply”, the opposite transmission building confirmation unit 121 collects, in S203, information on all the transmission devices (transmission devices in all the opposite buildings) connected to the transmission device in the target communication station building via transmission paths from connection information (topology information) on the transmission paths stored in the transmission path connection information DB 3.

In S204, the communication confirmation unit 122 uses the information collected in S203 to confirm communication from the transmission device in each opposite building to the transmission device in the target communication station building via the transmission NW monitoring device 35.

When it is confirmed in S205 that all the communication confirmation results by the communication confirmation unit 122 are no good, the building power source exhaustion determination unit 123 determines in S206 that the power source of the target communication station building is exhausted.

For example, in a case where there are 10 transmission devices as the transmission devices in the opposite buildings, which are opposite to the target communication station building, the building power source exhaustion determination unit 123 determines that the power source of the target communication station building is exhausted in a case of confirming that all of the 10 transmission devices are uncommunicable.

However, for example, in a case where there is an opposite transmission device connected to a very reliable transmission path, communication confirmation may be performed only on a part of transmission devices, which includes the transmission device, and it may be determined that the power source of the target communication station building is exhausted if all of the transmission devices are uncommunicable. For example, in a case where there are 10 transmission devices as the transmission devices in the opposite buildings, which are opposite to the target communication station building, communication confirmation may be performed on five devices including an opposite transmission device connected to a very reliable transmission path, and it may be determined that the power source of the target communication station building is exhausted in a case where it is confirmed that all of the five devices are uncommunicable.

### (Hardware Configuration Example)

Each of the communication building power source status confirmation system, the power outage confirmation device, and the power source exhaustion confirmation device can be implemented, for example, by causing a computer to execute a program. This computer may be a physical computer, or may be a virtual machine on a cloud. Hereinafter, the communication building power source status confirmation system, the power outage confirmation device, and the power source exhaustion confirmation device are collectively referred to as a device.

That is, the device can be implemented by a program corresponding to processing performed by the device being executed by use of hardware resources such as a CPU and a memory built in the computer. The above program can be stored and distributed by being recorded in a computer-readable recording medium (portable memory or the like). The above program can also be provided through a network such as the Internet or an electronic mail.

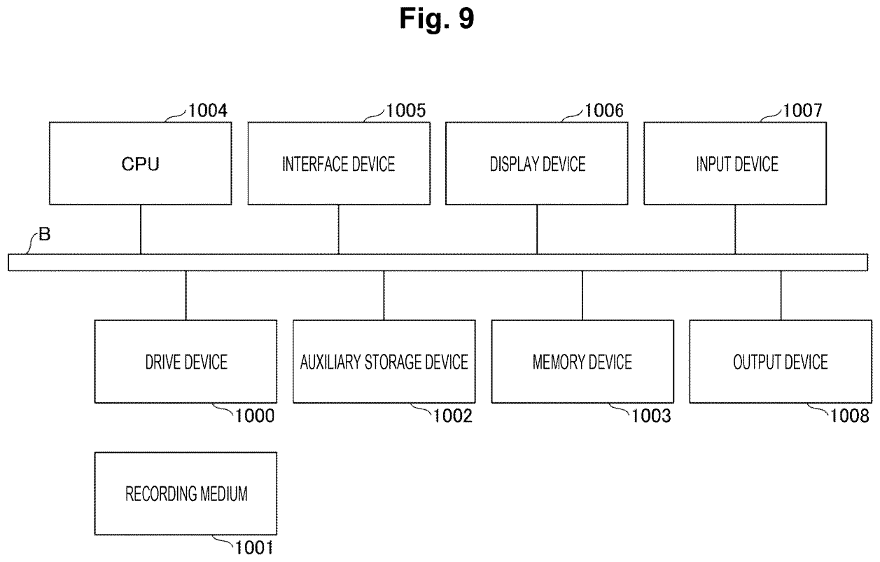

FIG. 9 is a diagram illustrating a hardware configuration example of the above computer. The computer in FIG. 9 includes a drive device 1000, an auxiliary storage device 1002, a memory device 1003, a CPU 1004, an interface device 1005, a display device 1006, an input device 1007, an output device 1008, and the like, which are connected to each other by a bus B.

The program for implementing the processing in the computer is provided by a recording medium 1001 such as a CD-ROM or a memory card. When the recording medium 1001 storing the program is set in the drive device 1000, the program is installed from the recording medium 1001 to the auxiliary storage device 1002 via the drive device 1000. However, the program is not necessarily installed from the recording medium 1001, and may be downloaded from another computer via a network. The auxiliary storage device 1002 stores the installed program, and also stores necessary files, data, and the like.

When an instruction to start the program is made, the memory device 1003 reads the program from the auxiliary storage device 1002 and stores the program. The CPU 1004 implements a function related to the device in accordance with the program stored in the memory device 1003. The interface device 1005 is used as an interface for connection to a network or the like. The display device 1006 displays a graphical user interface (GUI) or the like according to the program. The input device 1007 includes a keyboard and a mouse, buttons, a touch panel, or the like, and is used to input various operation instructions. The output device 1008 outputs a calculation result.

### Effects of Embodiment

With the technique according to the present embodiment, even if a failure occurs in a power monitoring network and a power supply status is unknown, the power supply status of a communication station building can be grasped through information obtained from a communication NW.

Therefore, it is possible to appropriately prepare for failure repair of the communication NW, and it is possible to reduce wasteful operation such as idling of one dispatch included in double dispatch.

### (Supplement)

The present specification discloses at least a power outage confirmation device, a power source exhaustion confirmation device, a power outage confirmation method, and a power source exhaustion confirmation method, and a program according to the following clauses.

### (Clause 1)

A power outage confirmation device that confirms whether a power outage has occurred in an area including a communication building and a plurality of subscribed users accommodated in the communication building,
the power outage confirmation device including:
a user confirmation unit that acquires information on the plurality of subscribed users in a case where a communication abnormality is detected from a power monitoring device;
a subscription log confirmation unit that confirms a log of an in-home device of each of the subscribed users on the basis of the information; and
a power outage determination unit that determines whether a power outage has occurred in the area on the basis of the log.

### (Clause 2)

The power outage confirmation device according to clause 1, wherein
the power outage determination unit determines that a power outage has occurred in the area in a case of confirming power-off logs in logs of in-home devices of subscribed users whose number is equal to or greater than a threshold within a certain time section, the subscribed users being included in the plurality of subscribed users.

### (Clause 3)

A power source exhaustion confirmation device that confirms whether a power source of a communication building is exhausted,
the power source exhaustion confirmation device including:
an opposite transmission device confirmation unit that acquires information on a plurality of transmission devices connected to a transmission device in the communication building via transmission paths in a case where a communication abnormality is detected from a power monitoring device;
a communication confirmation unit that confirms communication from each of a part or all of the plurality of transmission devices to the transmission device in the communication building; and
a power source exhaustion determination unit that determines whether the power source of the communication building is exhausted on the basis of a result of the communication confirmation by the communication confirmation unit.

### (Clause 4)

The power source exhaustion confirmation device according to clause 3, wherein
the power source exhaustion determination unit determines that the power source of the communication building is exhausted in a case where communication cannot be confirmed in any of the plurality of transmission devices.

### (Clause 5)

A power outage confirmation method executed by a power outage confirmation device that confirms whether a power outage has occurred in an area including a communication building and a plurality of subscribed users accommodated in the communication building,
the power outage confirmation method including:
a user confirmation step of acquiring information on the plurality of subscribed users in a case where a communication abnormality is detected from a power monitoring device;
a subscription log confirmation step of confirming a log of an in-home device of each of the subscribed users on the basis of the information; and
a power outage determination step of determining whether a power outage has occurred in the area on the basis of the log.

### (Clause 6)

A power source exhaustion confirmation method executed by a power source exhaustion confirmation device that confirms whether a power source of a communication building is exhausted,
the power source exhaustion confirmation method including:
an opposite transmission device confirmation step of acquiring information on a plurality of transmission devices connected to a transmission device in the communication building via transmission paths in a case where a communication abnormality is detected from a power monitoring device;
a communication confirmation step of confirming communication from each of a part or all of the plurality of transmission devices to the transmission device in the communication building; and
a power source exhaustion determination step of determining whether the power source of the communication building is exhausted on the basis of a result of the communication confirmation by the communication confirmation step.

### (Clause 7)

A program for causing a computer to function as each unit in the power outage confirmation device according to clause 1 or 2.

### (Clause 8)

A program for causing a computer to function as each unit in the power source exhaustion confirmation device according to clause 3 or 4.

Although the present embodiment has been described above, the present invention is not limited to the specific embodiment, and various modifications and changes can be made within the scope of the gist of the present invention described in the claims.

### REFERENCE SIGNS LIST

1 Accommodated user information DB
2 Monitoring log DB
3 Transmission path connection information DB
10 Power supply device
20 Power monitoring device
30 NW monitoring device
35 Transmission NW monitoring device
40 Power monitoring network
50 Subscription NW monitoring device
70, 80-1 to 80-4 Transmission device
100 Communication building power source status confirmation system
110 Commercial power outage confirmation unit
111 Area confirmation unit
112 Subscription log confirmation unit
113 Commercial power outage determination unit
120 Power source exhaustion confirmation unit
121 Opposite transmission building confirmation unit
122 Communication confirmation unit
123 Building power source exhaustion determination unit
1000 Drive device
1001 Recording medium
1002 Auxiliary storage device
1003 Memory device
1004 CPU
1005 Interface device
1006 Display device
1007 Input device
1008 Output device

1. A power outage confirmation apparatus configured to confirm whether a power outage has occurred in an area including a communication building and a plurality of subscribed users that are accommodated in the communication building, the power outage confirmation apparatus comprising:
circuitry configured to
acquire information on the plurality of subscribed users, upon occurrence of a condition in which a communication abnormality is detected by a power monitoring device;
confirm a log of an in-home device of each of the subscribed users based on the information; and
determine whether the power outage has occurred in the area based on the log.

2. The power outage confirmation apparatus according to claim 1, wherein the circuitry is configured to determine that the power outage has occurred in the area in a case of confirming power-off logs in logs of in-home devices of subscribed users whose number is equal to or greater than a threshold within a time section, the subscribed users being included in the plurality of subscribed users.

3. A power supply depletion confirmation apparatus configured to confirm whether a power source of a communication building is depleted, the power supply depletion confirmation apparatus comprising:
circuitry configured to
acquire information on a plurality of first transmission devices connected to a second transmission device in the communication building via one or more transmission paths, upon occurrence of a condition in which a communication abnormality is detected by a power monitoring device;
confirm communication from each of a part or all of the plurality of first transmission devices to the second transmission device in the communication building; and
determine whether the power source of the communication building is depleted based on a confirmation result of the communication.

4. The power supply depletion confirmation apparatus according to claim 3, wherein the circuitry is configured to determine that the power source of the communication building is depleted upon occurrence of a condition in which the communication from all of the first transmission devices is not confirmed.

5. A power outage confirmation method executed by a power outage confirmation apparatus that confirms whether a power outage has occurred in an area including a communication building and a plurality of subscribed users that are accommodated in the communication building, the power outrage confirmation method comprising:
acquiring information on the plurality of subscribed users upon occurrence of a condition in which a communication abnormality is detected by a power monitoring device:
confirming a log of an in-home device of each of the subscribed users based on the information; and
determining whether the power outage has occurred in the area based on the log.

6. (canceled)

7. A non-transitory computer storage medium storing a program for causing a computer to execute processing as in the power outage confirmation apparatus of claim 1.

8. A non-transitory computer storage medium storing a program for causing a computer to execute processing as in the power supply depletion confirmation apparatus of claim 3.
